(19) United States
(12) Patent Application Publication
(10) Pub. No.: US 2025/0386647 A1
(43) Pub. Date: Dec. 18, 2025

(54) DISPLAY DEVICE, METHOD OF MANUFACTURING DISPLAY DEVICE, ELECTRONIC DEVICE COMPRISING DISPLAY DEVICE

(71) Applicant: Samsung Display Co., LTD., Yongin-si (KR)

(72) Inventors: Ji Wook MOON, Yongin-si, Gyeonggi-do (KR); Jong Moo HUH, Yongin-si, Gyeonggi-do (KR); Min Woo KIM, Yongin-si, Gyeonggi-do (KR); Gwang Geun LEE, Yongin-si, Gyeonggi-do (KR)

(73) Assignee: Samsung Display Co., LTD., Yongin-si (KR)

(21) Appl. No.: 19/092,308

(22) Filed: Mar. 27, 2025

(30) Foreign Application Priority Data
Jun. 17, 2024 (KR) 10-2024-0078355
Jun. 28, 2024 (KR) 10-2024-0085001

(51) Int. Cl. H10H 29/851; H10H 29/01; H10H 29/37

(52) U.S. Cl. CPC H10H 29/8514; H10H 29/012; H10H 29/0361; H10H 29/37

(57) ABSTRACT

A display device including sub-pixel areas including a first sub-pixel area, a second sub-pixel area, and a third sub-pixel area includes: light-emitting elements which are disposed on a base layer and include a first light-emitting element in the first sub-pixel area, a second light-emitting element in the second sub-pixel area, and a third light-emitting element in the third sub-pixel area; a first color conversion layer in the first sub-pixel area, a second color conversion layer in the second sub-pixel area, and a scattering layer in the third sub-pixel area, which are disposed on the light-emitting elements; and a bank which is disposed between the sub-pixel areas and includes a substrate material on which semiconductor layers grow.

### CROSS-REFERENCE TO RELATED APPLICATION(S)

This application claims priority to and benefits of Korean Patent Application No. 10-2024-0078355, filed on Jun. 17, 2024, and Korean Patent Application No. 10-2024-0085001, filed on Jun. 28, 2024, under 35 U.S.C. § 119, in the Korean Intellectual Property Office (KIPO), the entire contents of which are incorporated herein by reference.

### BACKGROUND

### 1. Technical Field

The disclosure relates to a display device, a method of manufacturing the display device, and an electronic device comprising the display device.

### 2. Description of the Related Art

In recent years, as interest in information displays increases, research and development of display devices has been carried out continuously.

A display device implements a full-color display structure by various methods. For example, the display device may include a full-color display structure including sub-pixels including color conversion particles. In order to clearly implement the sub-pixels using the color conversion particles, there may be a need to secure sufficient area for the color-conversion particles to be placed.

### SUMMARY

One aspect of the disclosure is to provide a display device, a method of manufacturing the display device, and an electronic device comprising the display device, wherein an area in which color conversion particles are disposed can be sufficiently secured.

One aspect of the disclosure is to provide a display device which can have a high resolution display quality, a method of manufacturing the display device, and an electronic device comprising the display device.

One aspect of the disclosure is to provide a display device, a method of manufacturing the display device, and an electronic device comprising the display device, wherein process steps can be simplified.

A display device according to an embodiment of the disclosure including sub-pixel areas including a first sub-pixel area, a second sub-pixel area, and a third sub-pixel area may include: light-emitting elements which are disposed on a base layer and include a first light-emitting element in the first sub-pixel area, a second light-emitting element in the second sub-pixel area, and a third light-emitting element in the third sub-pixel area; a first color conversion layer in the first sub-pixel area, a second color conversion layer in the second sub-pixel area, and a scattering layer in the third sub-pixel area, which are disposed on the light-emitting elements; and a bank which is disposed between the sub-pixel areas and includes a substrate material on which semiconductor layers grow.

According to an embodiment, the bank may include at least one of a sapphire material, a silicon (Si) material, gallium arsenide (GaAs), silicon carbide (SiC), and gallium nitride (GaN).

According to an embodiment, at least a portion of each of the first color conversion layer, the second color conversion layer, and the scattering layer may be disposed in an accommodating space formed closer to the base layer than the bank.

According to an embodiment, the display device may further include an upper reflective layer disposed on a side surface of the bank; and an upper scattering layer disposed on the upper reflective layer.

According to an embodiment, the display device may further include an intermediate reflective structure which is disposed between the sub-pixel areas and extends longer in a thickness direction of the base layer than the light-emitting elements.

According to an embodiment, the bank may be disposed on the intermediate reflective structure.

According to an embodiment, a portion of the intermediate reflective structure may overlap the light-emitting elements in a direction that the base layer extends, and another portion of the intermediate reflective structure may overlap the first color conversion layer, the second color conversion layer, and the scattering layer in the direction.

According to an embodiment, the intermediate reflective structure may include an intermediate reflective layer, an intermediate scattering layer on the intermediate reflective layer, and a passivation layer on the intermediate scattering layer.

According to an embodiment, the first light-emitting element, the second light-emitting element, and the third light-emitting element may provide light of a same color.

According to an embodiment, the display device may further include a semiconductor wafer including the base layer and pixel circuits electrically connected to the light-emitting elements. The semiconductor wafer may be a complementary metal oxide semiconductor (CMOS) wafer.

According to an embodiment, each of the light-emitting elements may include a first semiconductor layer, a second semiconductor layer, and an active layer between the first semiconductor layer and the second semiconductor layer. The display device may further include a first conductive member adjacent to a side surface of each of the first semiconductor layer, the second semiconductor layer, and the active layer; and a second conductive member adjacent to another side surface of the second semiconductor layer.

According to an embodiment, the display device may further include a first conductive portion which is disposed on the semiconductor wafer and is electrically connected to the first conductive member, and a second conductive portion which is disposed on the semiconductor wafer and is electrically connected to the second conductive member.

According to an embodiment, the display device may further include a lower reflective layer which is disposed between the first conductive portion and the second conductive portion below the light-emitting elements.

According to an embodiment, the display device may further include a first color filter in the first sub-pixel area; a second color filter in the second sub-pixel area; and a third color filter in the third sub-pixel area.

A method of manufacturing a display device according to an embodiment of the disclosure may include patterning a structure including light-emitting elements on a substrate, providing a semiconductor wafer, bonding the semiconductor wafer with the structure, removing at least a portion of the substrate to form a bank, and patterning a color conversion layer in an area surrounded by the bank.

According to an embodiment, the patterning of the structure may include patterning an intermediate reflective structure including an intermediate reflective layer between the light-emitting elements on the substrate.

According to an embodiment, the method may further include forming a bank base with a reduced thickness of the substrate by removing at least a portion of the substrate, and patterning the bank by removing at least a portion of the bank base.

According to an embodiment, the patterning of the structure may include patterning a base un-doped semiconductor layer on the light-emitting elements. The method may further include forming an accommodating space by removing at least a portion of the base un-doped semiconductor layer, after the patterning of the bank.

According to an embodiment, the method may further include patterning an upper reflective layer and an upper scattering layer on a side surface of the bank.

According to an embodiment, the patterning of the color conversion layer may provide at least a portion of the color conversion layer in the accommodating space.

An electronic device according to an embodiment of the disclosure, may include a processor that provides input image data, a display device that displays an image based on the input image data, and a power supply that supplies power to the display device. The display device may include a first sub-pixel area, a second sub-pixel area, and a third sub-pixel area, light-emitting elements which are disposed on a base layer and comprise a first light-emitting element in the first sub-pixel area, a second light-emitting element in the second sub-pixel area, and a third light-emitting element in the third sub-pixel area, a first color conversion layer in the first sub-pixel area, a second color conversion layer in the second sub-pixel area, and a scattering layer in the third sub-pixel area, which are disposed on the light-emitting elements, and a bank which is disposed between the sub-pixel areas and comprises a substrate material on which semiconductor layers grow.

According to embodiments of the disclosure, it may be possible to provide a display device, a method of manufacturing the display device, and an electronic device comprising the display device, wherein an area in which color conversion particles are disposed may be sufficiently secured.

According to embodiments of the disclosure, it may be possible to provide a display device, which has a high resolution display quality, a method of manufacturing the display device and an electronic device comprising the display device.

According to embodiments of the disclosure, it may be possible to provide a display device, a method of manufacturing the display device, and an electronic device comprising the display device, wherein process steps may be simplified.

### BRIEF DESCRIPTION OF THE DRAWINGS

FIG. 1 is a plan view schematically illustrating a display device according to an embodiment.

FIG. 2 is a schematic cross-sectional view of a display device according to an embodiment.

FIG. 3 is a schematic cross-sectional view of a display device according to an embodiment.

FIGS. 4 to 10 are schematic cross-sectional views illustrating process steps of a method of manufacturing a display device according to an embodiment.

FIG. 11 is a schematic block diagram illustrating an electronic device including a display device in accordance with an embodiment.

FIG. 12 is a schematic diagram illustrating an example where the electronic device of FIG. 11 is implemented as a smartphone.

FIG. 13 is a schematic diagram illustrating an example where the electronic device of FIG. 11 is implemented as a tablet computer.

### DETAILED DESCRIPTION OF THE EMBODIMENT

The disclosure may be variously altered and may take many forms, and specific embodiments are illustrated in drawings and described in detail in the detailed description. However, it is not intended to limit the disclosure to any particular form of disclosure and should be understood to include all changes, equivalents or substitutions that fall within the scope of ideas and technology of the disclosure.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure. Singular expressions include plural expressions, unless the context clearly means otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device, a method of manufacturing of the display device and an electronic device comprising the display device. Hereinafter, a display device, a method of manufacturing the display device, and an electronic device comprising the display device will be described with reference to the accompanying drawings.

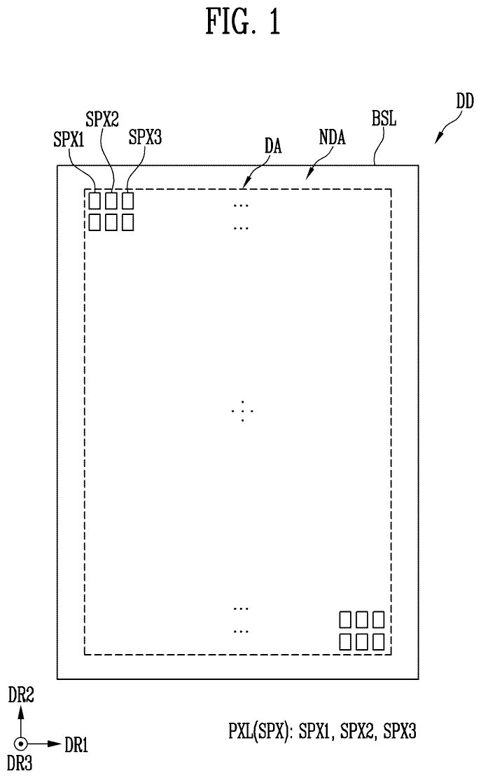

A display device DD according to some embodiments is described with reference to FIGS. 1 to 3.

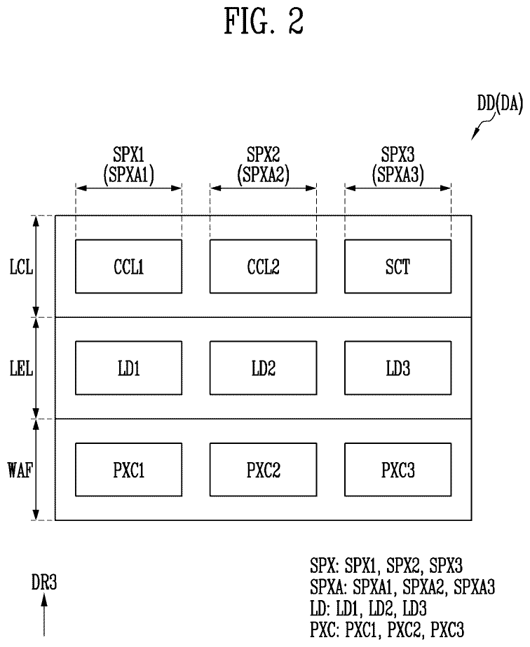

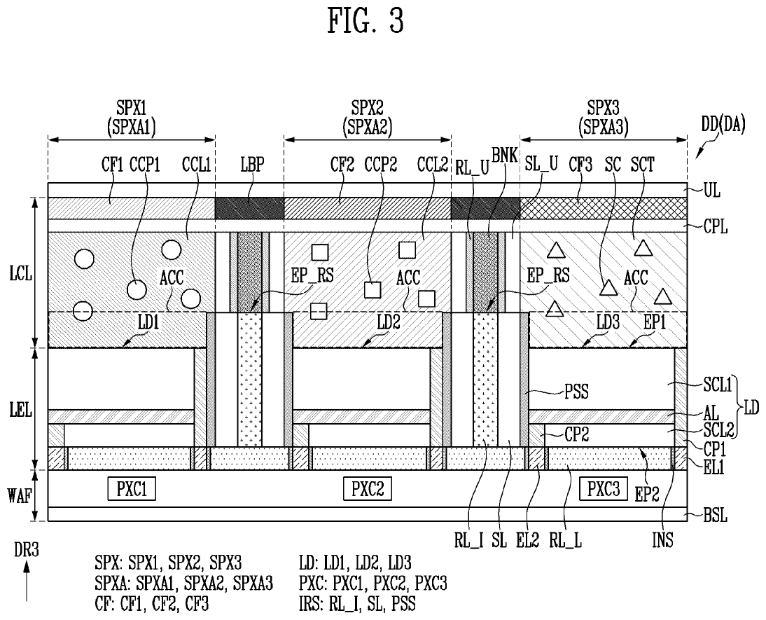

FIG. 1 is a plan view schematically illustrating a display device according to an embodiment. FIG. 2 is a schematic cross-sectional view of a display device according to an embodiment. FIG. 3 is a schematic cross-sectional view of a display device according to an embodiment.

Referring to FIG. 1, a display device (DD) may include a base layer (BSL) and pixels (PXL) disposed on the base layer (BSL). The display device (DD) may further include a driving circuit unit (e.g., a scan driving unit and a data driving unit), wirings, and pads for driving pixels (PXL).

The display device (DD) (or base layer (BSL)) may include a display area (DA) and a non-display area (NDA). The non-display area (NDA) may be an area other than the display area (DA). The non-display area (NDA) may surround at least a portion of the display area (DA) in a plan view.

The base layer (BSL) may form a base surface of the display device (DD). According to embodiments, the base layer (BSL) may be a lower substrate for disposing layers which form the display device (DD). The base layer (BSL) may be a rigid or flexible substrate or film. For example, the base layer (BSL) may include a glass material. For example, the base layer (BSL) may include a silicone material. For example, the base layer (BSL) may include polyimide. However, the disclosure is not limited thereto.

The display area (DA) may be an area where pixels (PXL) are disposed. The non-display area (NDA) may be an area where pixels (PXL) are not disposed. A driving circuit unit, wirings, and pads, which are connected to the pixels (PXL) of the display area (DA), may be disposed in the non-display area (NDA).

According to an embodiment, the pixels (or sub-pixels (SPX)) may be arranged according to a stripe or PENTILE™ array structure, but the disclosure not limited thereto, and the pixels (PXL) (or sub-pixels (SPX)) may be arranged in various forms.

According to an embodiment, the pixels (PXL) (or sub-pixels (SPX)) may include a first sub-pixel (SPX1), a second sub-pixel (SPX2), and a third sub-pixel (SPX3). Each of the first sub-pixel (SPX1), the second sub-pixel (SPX2), and the third sub-pixel (SPX3) may be a sub-pixel. At least one first sub-pixel (SPX1), at least one second sub-pixel (SPX2), and at least one third sub-pixel (SPX3) may form a single pixel unit configured to emit light of various colors.

Each of the first sub-pixel (SPX1), the second sub-pixel (SPX2), and the third sub-pixel (SPX3) may emit light of a single color.

For example, the first sub-pixel (SPX1) may be a red pixel that emits light of red (e.g., a first color), the second sub-pixel (SPX2) may be a green pixel that emits light of green (e.g., a second color), and the third sub-pixel (SPX3) may be a blue pixel that emits light of blue (e.g., a third color). The red pixel may provide light in a wavelength band in a range of about 600 nm to about 750 nm. The green pixel may provide light in a wavelength band in a range of about 480 nm to about 560 nm. The blue pixel may provide light in a wavelength band in a range of about 370 nm to about 460 nm.

In some embodiments, the number of second sub-pixels (SPX2) may be greater than the number of first sub-pixels (SPX1) and the number of third sub-pixels (SPX3). However, the color, the type, and/or the number of the first sub-pixels (SPX1), the second sub-pixels (SPX2), and the third sub-pixels (SPX3), which form each pixel unit, are not limited to specific examples.

Referring to FIGS. 2 and 3, the display device (DD) may include a semiconductor wafer (WAF), a light-emitting element layer (LEL), and a light control layer (LCL).

According to embodiments, the display device (DD) may include sub-pixels (SPX), each forming a sub-pixel area (SPXA). Sub-pixel areas (SPXA) may be areas where single-color light is emitted.

The sub-pixel area (SPXA) may include a first sub-pixel area (SPXA1) which is formed by the first sub-pixel (SPX1) and from which light of the first color is provided, a second sub-pixel area (SPXA2) which is formed by the second sub-pixel (SPX2) and from which light of the second color is provided, and a third sub-pixel area (SPXA3) which is formed by a third sub-pixel (SPX3) and from which light of the third color is provided.

The semiconductor wafer (WAF) may include a base layer (BSL). The base layer (BSL) may form a base on which other configurations of the display device (DD) are disposed. The base layer (BSL) may include a silicon substrate.

In some embodiments, the semiconductor wafer (WAF) may include a pixel circuit (PXC) for driving sub-pixels (SPX), such as a complementary metal oxide semiconductor (CMOS) wafer.

The pixel circuit (PXC) may include a first pixel circuit (PXC1) configured to drive the first sub-pixel (SPX1) and electrically connected to a first light-emitting element (LD1) in the first sub-pixel area (SPXA1), a second pixel circuit (PXC2) configured to drive the second sub- pixel (SPX2) and electrically connected to a second light-emitting element (LD2) in the second sub-pixel area (SPXA2), and a third pixel circuit (PXC3) configured to drive the third sub-pixel (SPX3) and electrically connected to a third light-emitting element (LD3) in the third sub-pixel arca (SPXA3).

The light-emitting element layer (LEL) may be a layer from which light is provided. The light-emitting element layer (LEL) may include a light-emitting element (LD). The light-emitting element (LD) may include a first light-emitting element (LD1) included in the first sub-pixel (SPX1) and disposed in the first sub-pixel area (SPXA1), a second light-emitting element (LD2) included in the second sub-pixel (SPX2) and disposed in the second sub-pixel area (SPXA2), and a third light-emitting element (LD3) included in the third sub-pixel (SPX3) and disposed in the third sub-pixel area (SPXA3).

According to embodiments, the first and third light-emitting elements (LD1 to LD3) may provide light of a same color (e.g., light of the third color).

The light control layer (LCL) may include a first color conversion layer (CCL1), a second color conversion layer (CCL2), and a scattering layer (SCT).

The first color conversion layer (CCL1) may be a layer which is disposed in the first sub-pixel area (SPXA1) and forms the first sub-pixel (SPX1). The first color conversion layer (CCL1) may include first color conversion particles (CCP1) which convert light provided by the first light-emitting element (LD1) (e.g., light including a light component of the third color) into light of the first color. For example, the first color conversion layer (CCL1) may include a first quantum-dot which converts light of the third color into light of the first color. The first quantum-dot may absorb light of the third color and shift the wavelength according to the energy transition to emit light of the first color. The first quantum-dot may be dispersed in a matrix layer, such as an organic material included in the first color conversion layer (CCL1). According to another embodiment, the first color conversion layer (CCL1) may include a phosphor.

The second color conversion layer (CCL2) may be a layer which is disposed in the second sub-pixel area (SPXA2) and forms the second sub-pixel (SPX2). The second color conversion layer (CCL2) may include second color conversion particles (CCP2) which convert light (e.g., light including a light component of the third color) provided by the second light-emitting element (LD2) into light of the second color. For example, the second color conversion layer (CCL2) may include a second quantum-dot that converts light of the third color into light of the second color. The second quantum-dot may absorb light of the third color and shift the wavelength according to the energy transition to thereby emit light of the second color. The second quantum-dot may be dispersed in a matrix layer, such as an organic material included in the second color conversion layer (CCL2). According to another embodiment, the second color conversion layer (CCL2) may include a phosphor.

The scattering layer (SCT) may be disposed in the third sub-pixel area (SPXA3) and may be a layer for improving light output efficiency and viewing angle characteristics of the display device (DD). The scattering layer (SCT) may include a scatterer. The scatterer may be dispersed in a matrix layer, such as an organic material (e.g., a transparent organic material) included in the scattering layer (SCT). According to embodiments, the scatterer may include light-scattering particles. For example, the scatterer may include at least one of titanium oxide (TiOₓ), silica (SiOₓ) (e.g., silica bead, hollow silica, etc.), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure is not limited thereto.

Accordingly, the first to third light-emitting elements (LD1 to LD3) may provide light of a same color in each of the first to third sub-pixel areas (SPXA1 to SPXA3), but a light control layer (LCL) may be formed to provide a full-color display structure.

Referring to FIG. 3, the cross-sectional structure of the display device (DD) is schematically illustrated.

According to embodiments, the display device (DD) may include a first conductive portion (EL1), a second conductive portion (EL2), an insulating layer (INS), and a lower reflective layer (RL_L).

The first conductive portion (EL1) and the second conductive portion (EL2) may be disposed on the semiconductor wafer (WAF). The first conductive portion (EL1) and the second conductive portion (EL2) may be disposed on a same layer and may include a same conductive material.

The first conductive portion (EL1) may electrically connect a wiring in the semiconductor wafer (WAF), such as a cathode wiring, to a first conductive member (CP1). The second conductive wiring (EL2) may electrically connect the pixel circuit (PXC) to a second conductive member (CP2).

The insulating layer (INS) may be disposed on a side surface of each of the first conductive portion (EL1) and the second conductive portion (EL2).

The lower reflective layer (RL_L) may be disposed on the semiconductor wafer (WAF). The lower reflective layer (RL_L) may be disposed adjacent to the first and second conductive portions (EL1 and EL2) in a direction the base layer (BSL) extends.

The lower reflective layer (RL_L) may include a reflective material. The lower reflective layer (RL_L) may recycle light provided by the light-emitting element (LD) and improve the light output efficiency of the display device (DD).

According to embodiments, the display device (DD) may include the first conductive member (CP1) and the second conductive member (CP2).

The first conductive member (CP1) may be disposed on the first conductive portion (EL1). The first conductive member (CP1) may be disposed adjacent to the first and second semiconductor layers (SCL1 and SCL2) and a side surface of the active layer (AL). The first conductive member (CP1) may be disposed on a side surface of an intermediate reflective structure (IRS). The first conductive member (CP1) may electrically connect the first semiconductor layer (SCL1) to the first conductive portion (EL1).

The second conductive member (CP2) may be disposed on the second conductive portion (EL2). The second conductive member (CP2) may be disposed adjacent to another side surface of the second semiconductor layer (SCL2). The second conductive member (CP2) may be disposed on another side surface of the intermediate reflective structure (IRS). The second conductive member (CP2) may electrically connect the second semiconductor layer (SCL2) to the second conductive portion (EL2).

The light-emitting element (LD) may be disposed in the sub-pixel area (SPXA). The light-emitting element (LD) may be disposed on the lower reflective layer (RL_L). The light-emitting element (LD) may be disposed between adjacent intermediate reflective structures (IRS).

The light-emitting element (LD) may be configured to emit light. The light-emitting element (LD) may include a first semiconductor layer (SCL1), a second semiconductor layer (SCL2), and an active layer (AL) disposed between the first semiconductor layer (SCL1) and the second semiconductor layer (SCL2). The first semiconductor layer (SCL1), the second semiconductor layer (SCL2), and the active layer (AL) may be stacked in the thickness direction of the base layer (BSL) (e.g., in a third direction (DR3)).

The light-emitting element (LD) may have a first end (EP1) and a second end (EP2). According to embodiments, the first semiconductor layer (SCL1) may be adjacent to the first end (EP1) of the light-emitting element (LD), and the second semiconductor layer (SCL2) may be adjacent to the second end (EP2).

The first semiconductor layer (SCL1) may include a first conductivity type semiconductor. The first semiconductor layer (SCL1) may be disposed on the active layer (AL), and a type of the first semiconductor layer (SCL1) and a type of the second semiconductor layer (SCL2) may be different. For example, the first semiconductor layer (SCL1) may include an N-type semiconductor. For example, the first semiconductor layer (SCL1) may include at least one of InAlGaN, GaN, AlGaN, InGaN, AlN, and InN, and doped with a first conductivity type dopant such as Si, Ge, and Sn. However, the disclosure is not limited thereto. The first semiconductor layer (SCL1) may include other materials.

The active layer (AL) may be disposed between the first semiconductor layer (SCL1) and the second semiconductor layer (SCL2). The active layer (AL) may have a single-quantum well structure or a multi-quantum well structure. The position of the active layer (AL) is not to the embodiment shown in FIG. 3 and may vary depending on the type of light-emitting element (LD).

A clad layer doped with a conductive dopant may be formed on a side and/or another side of the active layer (AL). For example, the clad layer may include at least one of AlGaN and InAlGaN. However, the disclosure is not limited thereto.

The second semiconductor layer (SCL2) may include a second conductivity type semiconductor. The second semiconductor layer (SCL2) may be disposed on the active layer (AL), and a type of the first semiconductor layer (SCL1) and a type of the second semiconductor layer (SCL2) may be different. For example, the second semiconductor layer (SCL2) may include a P-type semiconductor. For example, the second semiconductor layer (SCL2) may include at least one of InAlGaN, GaN, AlGaN, InGaN, AlN, and InN, and doped with a second conductivity type dopant such as Ga, B, and Mg. However, the disclosure is not limited thereto. The second semiconductor layer (SCL2) may include other materials.

In case that a voltage higher than a threshold voltage is applied to the first end (EP1) and the second end (EP2) of the light emitting element (LD), electron-hole pairs may recombine with each other in the active layer (AL), and the light emitting clement (LD) may emit light. The light-emitting element (LD) may be used as a light source in a variety of devices by controlling the light emission of the light-emitting element (LD) using this principle.

The light-emitting element (LD) may have different widths on the first and second ends (EP1 and EP2).

The side surface of the light-emitting clement (LD) may form a slope with respect to the plane on which the base layer (BSL) is disposed, and may be extended in a vertical direction. However, the disclosure is not limited thereto.

According to embodiments, the display device (DD) may include intermediate reflective structures (IRS). The intermediate reflective structures (IRS) may include an intermediate reflective layer (RL_I), an intermediate scattering layer (SL), and a passivation layer (PSS).

The intermediate reflective structures (IRS) may be disposed between adjacent sub- pixel areas (SPXA). The intermediate reflective structures (IRS) may be disposed between adjacent light-emitting elements (LD). The intermediate reflective structures (IRS) may be disposed between adjacent first and second color conversion layers (CCL1 and CCL2) and the scattering layer (SCT).

The intermediate reflective structures (IRS) may be extended longer in the third direction (DR3) than the light-emitting element (LD). For example, the lower portions of the intermediate reflective structures (IRS) may overlap the light-emitting elements (LD), and the upper portions of the intermediate reflective structures (IRS) may overlap the first and second color conversion layers (CCL1 and CCL2) and the scattering layer (SCT), in the direction in which the sub-pixel areas (SPXA1 to SPXA3) are adjacent to each other.

The ends (EP_RS) of the intermediate reflective structures (IRS) may be formed in the light control layer (LCL). The ends (EP_RS) of the intermediate reflective structures (IRS) may be formed at a height more spaced from the base layer (BSL) than the light-emitting elements (LD).

The intermediate reflective layer (RL_I) may be formed inside the intermediate reflective structure (IRS) and may include a reflective material. The intermediate reflective layer (RL_I) may reflect light provided from the light-emitting element (LD).

The intermediate reflective layer (RL_I) may extend longer than the light-emitting element (LD) in the third direction (DR3), and may overlap the first and second color conversion layers (CCL1 and CCL2) and the scattering layer (SCT) along a direction the sub-pixel areas (SPXA) are spaced apart from each other.

In some embodiments, a light recycling structure, in which light provided from the light-emitting element (LD) may be directed to the first and second color conversion layers (CCL1 and CCL2) and the scattering layer (SCT) by a portion of the intermediate reflective layer (RL_I), may be provided. Accordingly, color conversion may occur more efficiently in the first and second color conversion layers (CCL1 and CCL2), which may improve color conversion efficiency in the light control layer (LCL), and the display device (DD) may display image information more clearly.

The intermediate scattering layer (SL) may be disposed between the intermediate reflective layer (RL_I) and the passivation layer (PSS). The intermediate scattering layer (SL) may scatter light reflected by the intermediate reflective layer (RL_I) and direct the light to the first and second color conversion layers (CCL1 and CCL2) and the scattering layer (SCT). The intermediate scattering layer (SL) may include at least one of the materials which are above-mentioned with reference to the scatterer (SC).

The passivation layer (PSS) may be disposed on the intermediate scattering layer (SL). The passivation layer (PSS) may be disposed between the intermediate scattering layer (SL) and the light-emitting element (LD), and between the intermediate scattering layer (SL) and the first and second color conversion layers (CCL1 and CCL2), and the scattering layer (SCT).

According to embodiments, the display device (DD) may include a bank (BNK).

The bank (BNK) may be disposed between adjacent sub-pixel areas (SPXA). The bank (BNK) may be included in the light control layer (LCL). The bank (BNK) may be disposed on an intermediate reflective structure (IRS). According to embodiments, the bank (BNK) may overlap the intermediate reflective layer (RL_I) in a plan view.

The bank (BNK) may form a space (e.g., an opening) in which the first and second color conversion layers (CCL1 and CCL2) and the scattering layer (SCT) may be provided. The bank (BNK) may protrude in the thickness direction of the base layer (BSL) (e.g., in the third direction (DR3)).

The bank (BNK) may include a substrate material that may grow semiconductor layers. According to embodiments, the bank (BNK) may include a substrate material for forming (e.g., growing) a first semiconductor layer (SCL1), an active layer (AL), and a second semiconductor layer (SCL2). For example, the bank (BNK) may include at least one of a sapphire material and a silicon (Si) material. However, the disclosure is not limited thereto. According to embodiments, the BNK may include at least one of Gallium Arsenide (GaAs), Silicon Carbide (SiC), and Gallium Nitride (GaN).

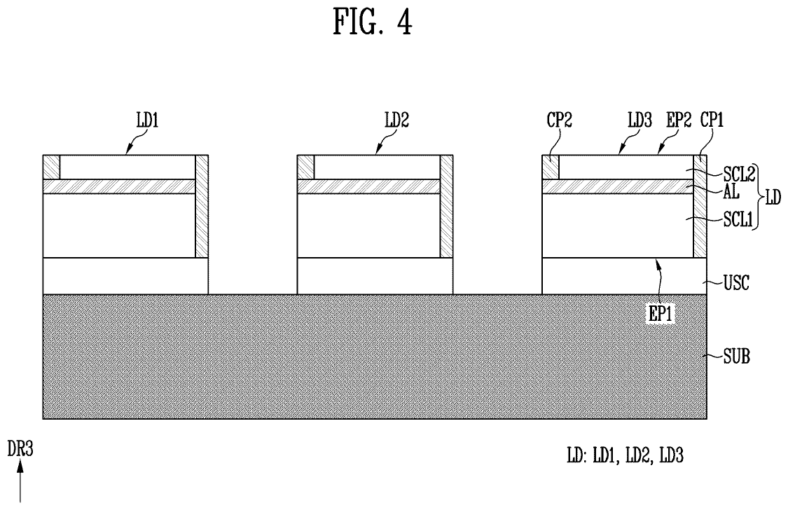

According to embodiments, the bank (BNK) may be a structure prepared by removing at least a portion of the substrate (SUB) (see FIG. 4) for growing the first semiconductor layer (SCL1), the active layer (AL), and the second semiconductor layer (SCL2). A bank structure that forms the space for forming the first and second color conversion layers (CCL1 and CCL2) and the scattering layer (SCT) may not be patterned in a separate process. In other words, according to an embodiment, the process steps may be simplified, and the process costs may be reduced.

According to embodiments, the display device (DD) may include an upper reflective layer (RL_U).

The upper reflective layer (RL_U) may be disposed on a side surface of the bank (BNK). The upper reflective layer (RL_U) may be disposed between adjacent sub-pixel areas (SPXA) and may include a reflective material. The upper reflective layer (RL_U) may reflect light provided from the first and second color conversion layers (CCL1 and CCL2) and the scattering layer (SCT), thereby improving color conversion efficiency in the first and second color conversion layers (CCL1 and CCL2) and scattering efficiency in the scattering layer (SCT).

According to embodiments, the display device (DD) may include an upper scattering layer (SL_U).

The upper scattering layer (SL_U) may be disposed on the upper reflective layer (RL_U). The upper scattering layer (SL_U) may scatter light reflected by the upper reflective layer (RL_U) and direct the light to the first and second color conversion layers (CCL1 and CCL2) and the scattering layer (SCT). The upper scattering layer (SL_U) may include at least one of the materials described above with reference to the scatterer (SC) discussed above.

The first and second color conversion layers (CCL1 and CCL2) and the scattering layer (SCT) may be disposed in the first to third sub-pixel areas (SPXA1 to SPXA3), respectively.

At least a portion of each of the first and second color conversion layers (CCL1 and CCL2) and the scattering layer (SCT) may be provided in an area surrounded by the bank (BNK). The first and second color conversion layers (CCL1 and CCL2) and the scattering layer (SCT) may overlap the intermediate reflective structure (IRS) in the direction in which adjacent sub-pixel areas SPXA are adjacent to each other (e.g. a direction in which the base layer (BSL) extends).

At least a portion of each of the first and second color conversion layers (CCL1 and CCL2) and the scattering layer (SCT) may be provided in the area surrounded by the intermediate reflective structure (IRS). The first and second color conversion layers (CCL1 and CCL2) and the scattering layer (SCT) may overlap the bank (BNK) in a direction in which the adjacent sub-pixel areas (SPXA) are adjacent to each other (e.g., a direction in which the base layer (BSL) extends).

For example, at least a portion of an un-doped semiconductor layer (USC) may be removed during the manufacturing process of the display device (DD). An area where the un-doped semiconductor layer (USC) has been removed may form an accommodating space (ACC). The accommodating space (ACC) may be formed in an area adjacent to the base layer (BSL) rather than the bank (BNK).

According to embodiments, at least a portion of each of the first and second color conversion layers (CCL1 and CCL2) and the scattering layer (SCT) may be provided in the accommodating space (ACC). In other words, according to some embodiments, the first and second color conversion layers (CCL1 and CCL2) and the scattering layer (SCT) may be disposed in the space formed by the bank (BNK) and may additionally be disposed in the accommodating space (ACC), and the area where the first and second color conversion layers (CCL1 and CCL2) and the scattering layer (SCT) are disposed may be expanded.

According to some embodiments, in order for a full-color display structure to be implemented, the first and second color conversion layers (CCL1 and CCL2) and the scattering layer (SCT) may be provided as a color conversion structure. In order for the color conversion to occur sufficiently in the first and second sub-pixels (SPX1, SPX2), the first and second color conversion layers (CCL1 and CCL2) may have a sufficient thickness.

According to some embodiments, at least a portion of each of the first and second color conversion layers (CCL1 and CCL2) and the scattering layer (SCT) may be provided in the accommodating space (ACC) in addition to the space formed by the bank (BNK), so that the first and second color conversion layers (CCL1 and CCL2) and the scattering layer (SCT) may have a sufficient thickness. Accordingly, the color conversion may sufficiently occur at the sub-pixels (SPX), and light scattering may occur appropriately.

According to embodiments, the display device (DD) may include a capping layer (CPL).

The capping layer (CPL) may cover the first and second color conversion layers (CCL1 and CCL2) and the scattering layer (SCT). The capping layer (CPL) may include an inorganic material.

According to embodiments, the display device (DD) (or light control layer (LCL)) may include color filters (CF) and a light blocking pattern layer (LBP).

The color filters (CF) may selectively transmit light of a color. For example, the color filters (CF) may include a first color filter (CF1) disposed in the first sub-pixel area (SPXA1), a second color filter (CF2) disposed in the second sub-pixel area (SPXA2), and the third color filter (CF3) disposed in the third sub-pixel area (SPXA3).

The first color filter (CF1) may include dyes or pigments that selectively transmit light of the first color. The second color filter (CF2) may include dyes or pigments that selectively transmit light of the second color. The third-color filter (CF3) may include dyes or pigments that selectively transmit light of the third color.

The light-blocking pattern layer (LBP) may be disposed between the sub-pixel areas (SPXA) and may block light. The light-blocking pattern layer (LBP) may include a black matrix material such as carbon black or may be formed by stacking the first to third color filters (CF1 to CF3) in the third direction DR3.

According to embodiments, the display device (DD) may include an upper layer (UL).

The upper layer (UL) may be disposed on the color filters (CF). The upper layer (UL) may include a cover window, etc., but the disclosure is not limited thereto.

Referring to FIGS. 4 to 10, a method of manufacturing a display device (DD) according to an embodiment is described.

For the convenience of explanation, information that may overlap the above-described information may be briefly described or may not be repeated.

FIGS. 4 to 10 are schematic cross-sectional views illustrating process steps of a method of manufacturing a display device according to an embodiment. For the convenience of explanation, FIGS. 4 to 10 are shown based on the aforementioned cross-sectional structure described with reference to FIG. 3.

According to some embodiments, after a structure, in which an intermediate reflective structure (IRS) and a light-emitting element (LD) are formed on a substrate (SUB), is disposed on a semiconductor wafer (WAF), the light control layer (LCL) may be disposed on the upper portion of the structure, so that a display device (DD) may be manufactured.

According to embodiments, a conductive or insulating layer on a base layer (BSL) and the substrate (SUB) may be formed by a normal process for manufacturing a semiconductor device. For example, the conductive or the insulating layer on the base layer (BSL) and the substrate (SUB) may be formed by a photolithography process, etched by a method (wet etching, dry etching, etc.), and deposited by a method (sputtering, chemical vapor deposition, etc.). The disclosure is not necessarily limited to a particular example.

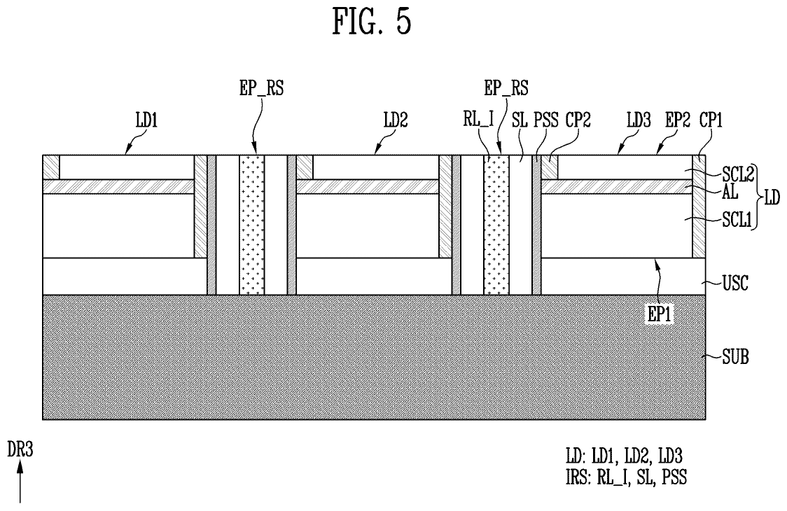

First, referring to FIGS. 4 and 5, process steps of forming a light-emitting element (LD) and an intermediate reflective structure (IRS) on the substrate (SUB) according to an embodiment are described.

Referring to FIG. 4, a substrate (SUB) for forming a semiconductor layer may be provided, and first and second conductive members (CP1 and CP2) adjacent to an un-doped semiconductor layer (USC) and first to third light-emitting elements (LD1 to LD3), respectively, may be patterned on the substrate (SUB).

In this step, the un-doped semiconductor layer, a first base semiconductor layer, a base active layer, and a second base semiconductor may be grown on the substrate (SUB), and at least a portion of each of the un-doped semiconductor part, the first base semiconductor layer, the base active layer, and the second base semiconductor may be etched to pattern the un-doped semiconductor layer (USC) and the first to the third light-emitting elements (LD1 to LD3).

The substrate (SUB) may be a base plate for growing semiconductor layers. For example, the substrate (SUB) may be a wafer for epitaxial growth of a single material.

The un-doped semiconductor layer may include a material for forming the un-doped semiconductor layer (USC), the first base semiconductor layer may include a material for forming the first semiconductor layer (SCL1), the base active layer may include a material for forming the active layer (AL), and the second base semiconductor layer may include a material for forming the second semiconductor layer (SCL2).

In this step, after the un-doped semiconductor layer (USC) and the first and third light-emitting elements (LD1 to LD3) are patterned, the first and second conductive members (CP1 and CP2) may be patterned. For example, the first semiconductor layer (SCL1) may be patterned to expose at least a portion of the upper surface of the un-doped semiconductor layer (USC), and the first conductive member (CP1) may be patterned to be formed adjacent to a side surface of the active layer (AL) and the first and second semiconductor layers (SCL1 and SCL2). At least a portion of the second semiconductor layer (SCL2) may be patterned to have a narrower width than the first semiconductor layer (SCL1), and the second conductive section (CP2) may be patterned to be formed adjacent to another side surface of the second semiconductor layer (SCL2).

Referring to FIG. 5, an intermediate reflective structure (IRS) may be patterned into an area between adjacent light-emitting elements (LD) (or an area between adjacent un-doped semiconductor layers (USC)).

In this step, a passivation layer (PSS) may be formed to cover the side surface of the un-doped semiconductor layers (USC) and the light-emitting element (LD), an intermediate scattering layer (SL) may be formed on the passivation layer (PSS), and an intermediate reflective layer (RL_I) may be formed on the intermediate scattering layer (SL).

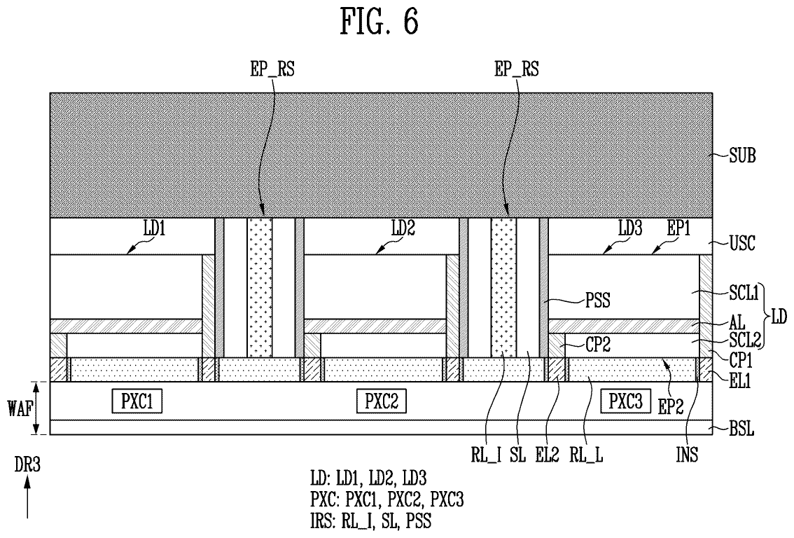

Process steps of forming a light-emitting element layer (LEL) and a light control layer (LCL) are described by disposing light-emitting elements (LD) on a semiconductor wafer (WAF) with reference to FIGS. 6 to 10.

Referring to FIG. 6, the semiconductor wafer (WAF) including a base layer (BSL) and a pixel circuit (PXC) may be provided, and a light-emitting element (LD), an intermediate reflective structure (IRS), and a substrate (SUB) may be disposed on the semiconductor wafer (WAF).

In this step, the semiconductor wafer (WAF) may be provided, and the first and second conductive portions (EL1 and EL2) and the lower reflective layer (RL_L) may be patterned on the semiconductor wafer (WAF).

In this step, the light-emitting elements (LD) and the intermediate reflective structure (IRS) may be disposed (e.g., bonded) on the semiconductor wafer (WAF) so that the light- emitting elements (LD) and intermediate reflective structures (IRS) are directed toward the semiconductor wafer (WAF). In this step, a structure, including the substrate (SUB), and the semiconductor wafer (WAF) may be bonded to each other using a wafer-to-wafer bonding method. For example, solder bonding or Cu-Cu hybrid bonding method may be used in this step. However, the disclosure is not limited thereto.

In this step, the first conductive portion (EL1) may be electrically connected to the first conductive member (CP1), and the second conductive portion (EL2) may be electrically connected to the second conductive member (CP2). Accordingly, the light-emitting element (LD) may be electrically connected to the pixel circuit (PXC).

In this step, the substrate (SUB) may be provided on the semiconductor wafer (WAF) and may be disposed on the un-doped semiconductor layer (USC). A side surface of the substrate (SUB) may be exposed.

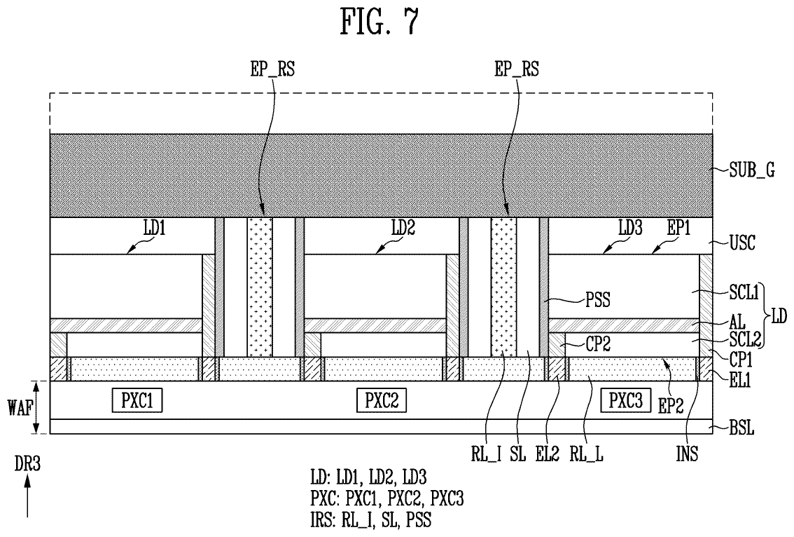

Referring to FIG. 7, at least a portion of the substrate may be removed, and a bank base SUB_G with a reduced thickness may be provided.

In this step, at least a portion of the substrate (SUB) may be removed so that the substrate (SUB) has a height of the bank (BNK) to be manufactured. Accordingly, no further process may be carried out to form a bank (BNK), and the height of the bank (BNK) may be appropriately defined.

In this step, a back grinding process for the substrate (SUB) may be performed. However, the disclosure is not limited thereto. A polishing process, etc. for the substrate (SUB) may also be performed.

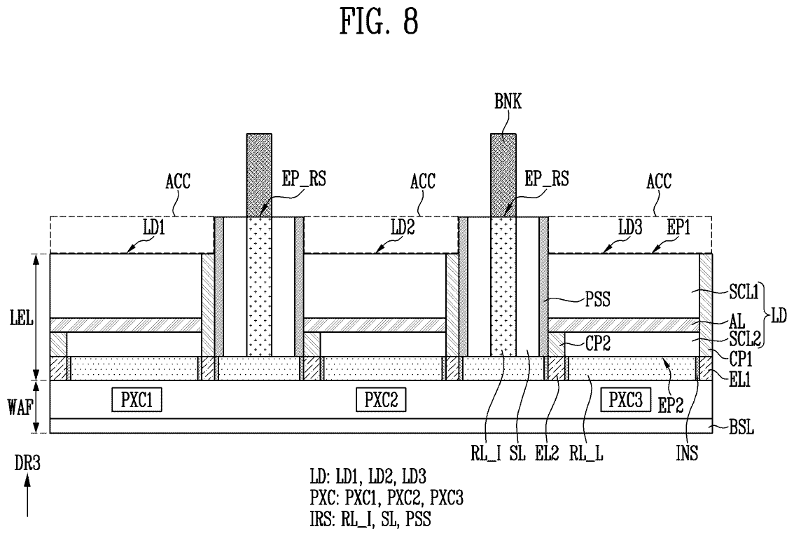

Referring to FIG. 8, at least a portion of the bank base (SUB_G) may be removed to form a bank (BNK), and at least a portion of the un-doped semiconductor layer (USC) may be removed to form an accommodating space (ACC).

In this step, at least a portion of the bank base (SUB_G) may be etched, and a bank, which exposes the un-doped semiconductor layer (USC) and forms an opening, may be formed. As described above, the bank (BNK) may be manufactured from the substrate (SUB), and the process steps may be simplified.

In this step, after the formation of the bank (BNK), at least a portion of the un-doped semiconductor layer (USC) may be removed from the area adjacent to the base layer (BSL) than the bank (BNK) to form the un-doped semiconductor layer (USC). Accordingly, an intermediate reflective structure (IRS) and an accommodating space (ACC) may be formed.

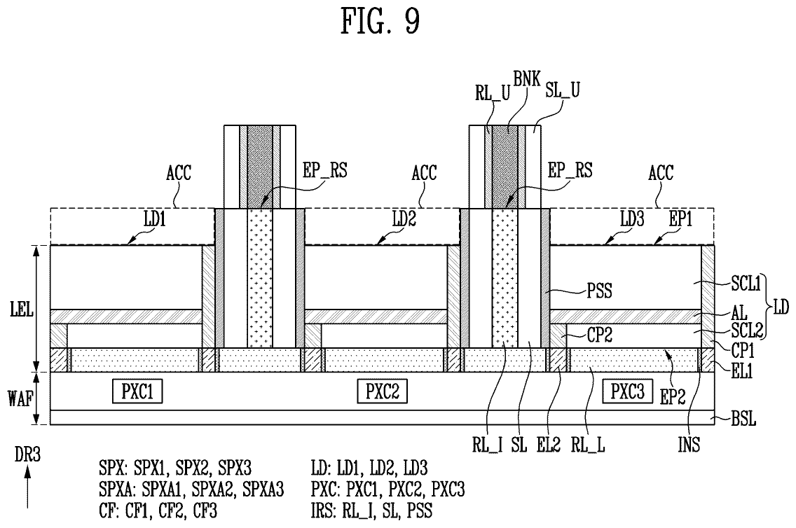

Referring to FIG. 9, an upper reflective layer (RL_U) and an upper scattering layer (SL_U) may be patterned on the side surface of the bank (BNK). Accordingly, reflective and scattering structures may be formed in an area higher than the area in which the light-emitting element (LD) is disposed.

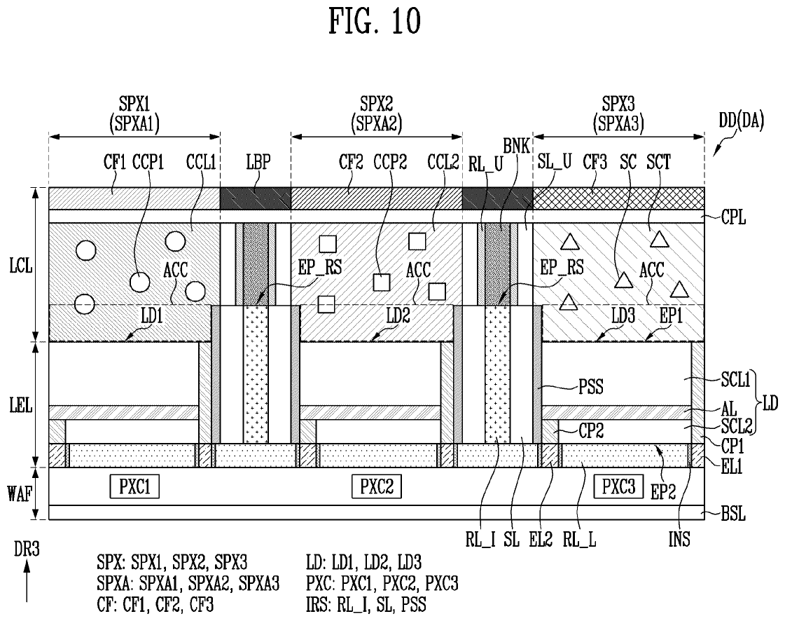

Referring to FIG. 10, the first and second color conversion layers (CCL1 and CCL2) and the scattering layer (SCT) may be patterned in the area surrounded by the bank (BNK) and the accommodating space (ACC). In an embodiment, color filters (CF) and the light-blocking pattern layer (LBP) may be patterned on the first and second color conversion layers (CCL1 and CCL2) and the scattering layer (SCT).

In this step, the first and second color conversion layers (CCL1 and CCL2) and the scattering layer (SCT) may be formed by a photolithography process or an inkjet process, etc. However, the disclosure is not necessarily limited thereto.

In this step, at least a portion of each of the first and second color conversion layers (CCL1 and CCL2) and the scattering layer (SCT) may be formed in the accommodating space (ACC).

As described above, the space in which the first and second color conversion layers (CCL1 and CCL2) and scattering layers (SCT) are disposed may be expanded to further improve the color conversion efficiency and scattering efficiency.

Subsequently, in some embodiments, an upper layer (UL) may be disposed on the color filters (CF) to provide the display device (DD) according to the embodiments.

Hereinafter, an electronic device 1000 including the display device DD in accordance with an embodiment will be described.

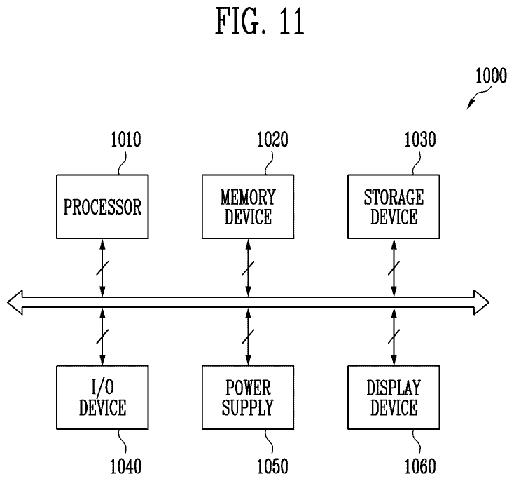

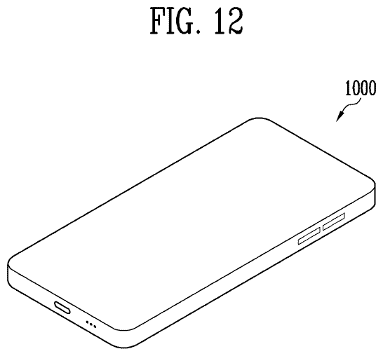

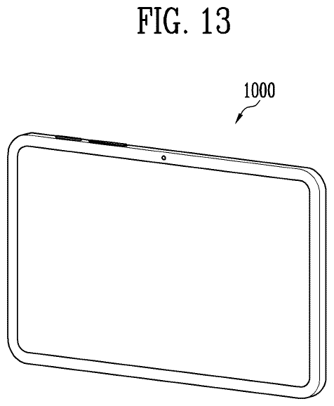

FIG. 11 is a schematic block diagram illustrating an electronic device 1000 including a display device in accordance with an embodiment. FIG. 12 is a schematic diagram illustrating an example where the electronic device 1000 of FIG. 11 is implemented as a smartphone. FIG. 13 is a schematic diagram illustrating an example where the electronic device 1000 of FIG. 11 is implemented as a tablet computer.

Referring to FIGS. 12 to 13, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 12, the electronic device 1000 may be a smartphone. In an embodiment, as illustrated in FIG. 13, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device including sub-pixel areas comprising a first sub-pixel area, a second sub-pixel area, and a third sub-pixel area, the display device comprising:
light-emitting elements which are disposed on a base layer and comprise a first light-emitting element in the first sub-pixel area, a second light-emitting element in the second sub-pixel area, and a third light-emitting element in the third sub-pixel area;
a first color conversion layer in the first sub-pixel area, a second color conversion layer in the second sub-pixel area, and a scattering layer in the third sub-pixel area, which are disposed on the light-emitting elements; and
a bank which is disposed between the sub-pixel areas and comprises a substrate material on which semiconductor layers grow.

2. The display device according to claim 1, wherein the bank comprises at least one of a sapphire material, a silicon (Si) material, gallium arsenide (GaAs), silicon carbide (SiC), and gallium nitride (GaN).

3. The display device according to claim 1, wherein at least a portion of each of the first color conversion layer, the second color conversion layer, and the scattering layer is disposed in an accommodating space formed closer to the base layer than the bank.

4. The display device according to claim 3, further comprising:
an upper reflective layer disposed on a side surface of the bank; and
an upper scattering layer disposed on the upper reflective layer.

5. The display device according to claim 3, further comprising:
an intermediate reflective structure which is disposed between the sub-pixel areas and extends longer in a thickness direction of the base layer than the light-emitting elements.

6. The display device according to claim 5, wherein the bank is disposed on the intermediate reflective structure.

7. The display device according to claim 6, wherein
a portion of the intermediate reflective structure overlaps the light-emitting elements in a direction that the base layer extends, and
another portion of the intermediate reflective structure overlaps the first color conversion layer, the second color conversion layer, and the scattering layer in the direction.

8. The display device according to claim 7, wherein the intermediate reflective structure comprises an intermediate reflective layer, an intermediate scattering layer on the intermediate reflective layer, and a passivation layer on the intermediate scattering layer.

9. The display device according to claim 7, wherein the first light-emitting element, the second light-emitting element, and the third light-emitting element provide light of a same color.

10. The display device according to claim 1, further comprising:
a semiconductor wafer comprising the base layer and pixel circuits electrically connected to the light-emitting elements,
wherein the semiconductor wafer is a complementary metal oxide semiconductor (CMOS) wafer.

11. The display device according to claim 10, wherein
each of the light-emitting elements comprises a first semiconductor layer, a second semiconductor layer, and an active layer between the first semiconductor layer and the second semiconductor layer, and
the display device further comprises:
a first conductive member adjacent to a side surface of each of the first semiconductor layer, the second semiconductor layer, and the active layer; and
a second conductive member adjacent to another side surface of the second semiconductor layer.

12. The display device according to claim 11, further comprising:
a first conductive portion which is disposed on the semiconductor wafer and is electrically connected to the first conductive member; and
a second conductive portion which is disposed on the semiconductor wafer and is electrically connected to the second conductive member.

13. The display device according to claim 12, further comprising:
a lower reflective layer which is disposed between the first conductive portion and the second conductive portion below the light-emitting elements;
a first color filter in the first sub-pixel area;
a second color filter in the second sub-pixel area; and
a third color filter in the third sub-pixel area.

14. A method of manufacturing a display device, the method comprising:
patterning a structure comprising light-emitting elements on a substrate;
providing a semiconductor wafer;
bonding the semiconductor wafer with the structure;
removing at least a portion of the substrate to form a bank; and
patterning a color conversion layer in an area surrounded by the bank.

15. The method according to claim 14, wherein the patterning of the structure comprises patterning an intermediate reflective structure comprising an intermediate reflective layer between the light-emitting elements on the substrate.

16. The method according to claim 15, further comprising:
forming a bank base with a reduced thickness of the substrate by removing at least a portion of the substrate; and
patterning the bank by removing at least a portion of the bank base.

17. The method according to claim 16, wherein
the patterning of the structure comprises patterning a base un-doped semiconductor layer on the light-emitting elements, and
the method further comprises forming an accommodating space by removing at least a portion of the base un-doped semiconductor layer, after the patterning of the bank.

18. The method according to claim 17, further comprising:
patterning an upper reflective layer and an upper scattering layer on a side surface of the bank.

19. The method according to claim 17, wherein the patterning of the color conversion layer comprises providing at least a portion of the color conversion layer in the accommodating space.

20. An electronic device, comprising:
a processor that provides input image data;
a display device that displays an image based on the input image data; and
a power supply that supplies power to the display device,
wherein the display device comprises:
a first sub-pixel area, a second sub-pixel area, and a third sub-pixel area;
light-emitting elements which are disposed on a base layer and comprise a first light-emitting element in the first sub-pixel area, a second light-emitting element in the second sub-pixel area, and a third light-emitting element in the third sub-pixel area;
a first color conversion layer in the first sub-pixel area, a second color conversion layer in the second sub-pixel area, and a scattering layer in the third sub-pixel area, which are disposed on the light-emitting elements; and
a bank which is disposed between the sub-pixel areas and comprises a substrate material on which semiconductor layers grow.
